(19) United States
(12) Patent Application Publication
(10) Pub. No.: US 2012/0306031 A1
(43) Pub. Date: Dec. 6, 2012

(54) SEMICONDUCTOR SENSOR DEVICE AND METHOD OF PACKAGING SAME

(75) Inventors: Wai Yew Lo, Petaling Jaya (MY); Lan Chu Tan, Shah Alam (MY)

(73) Assignee: FREESCALE SEMICONDUCTOR, INC., Austin, TX (US)

(21) Appl. No.: 13/118,596

(22) Filed: May 31, 2011

(51) Int. Cl. H01L 29/84; H01L 21/54

(52) U.S. Cl. 257/415; 438/51; 257/E29.324; 257/E21.501

(57) ABSTRACT

A semiconductor sensor die is packaged with a footed lid that has side walls and a top portion with a central hole. Gel material is dispensed into a cavity formed by the side walls such that it covers the die prior to attaching the lid top portion.

### BACKGROUND OF THE INVENTION

The present invention relates generally to packaging of semiconductor devices, and more particularly to a method of assembling semiconductor sensor device.

Semiconductor sensor devices such as pressure sensor devices are well known. Pressure sensor dies are susceptible to mechanical damage during handling and packaging. For this reason, these sensor dies are typically mounted in pre-molded packages and then sealed in the packages using a separate cover/lid.

One way of packaging the semiconductor dies is to mount the dies to a pre-molded lead frame and encapsulate the die and pre-molded lead frame with a mold compound. For example, current cavity QFN (Quad Flat No lead) packages require the lead frame to be pre-molded to create a cavity for a gel coating that covers the sensor. However, the premold process is not robust, often low yielding and may result in mold related defects.

Further, dies such as piezo resistive transducer (PRT), parameterized layout cell (Pcell) and Gyro do not allow full encapsulation because that would impede their functionality. As a result, the premolded lead frame requires that a metal lid or cap be placed on the mold wall to protect the dies from the outside environment. However, premolded lead frames are relatively expensive, which makes the overall packaging costs unattractive. The same applies if a premolded substrate is used instead of a premolded lead frame.

Packages with premolded lead frames or premolded substrates have other associated issues such as mold flashing and voids, mold-die paddle co-planarity and cavity height inconsistency.

Accordingly, it would be advantageous to be able to efficiently package semiconductor dies in which the risk of environmental damage to the die is substantially reduced or eliminated while reducing the overall packaging costs.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 is a cross-sectional view of a semiconductor device package in accordance with one embodiment of the present invention;

FIG. 2 is a side cross-sectional view showing a plurality of lead frames with an adhesive tape attached to the lead frames;

FIG. 3 is an illustration of a step of attaching semiconductor dies to respective ones of the die pads of the lead frames;

FIG. 4 shows the step of electrically connecting the semiconductor dies to respective lead frames;

FIG. 5 shows the step of attaching side walls of a footed lid to each of the lead frames;

FIG. 6 shows the step of dispensing a gel material within each of the cavities formed by the footed lid;

FIG. 7 is a side cross-sectional view showing a top cover attached to the side walls of the footed lid;

FIG. 8 shows the step of removing the tape from the lead frames; and

FIG. 9 illustrates a step of separating the array of packaged semiconductor devices into individual packaged semiconductor devices.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention provides a method of packaging a semiconductor die. The method includes providing a plurality of lead frames or a substrate (printed wiring board). Each of the plurality of lead frames includes a die pad and a plurality of lead fingers. A tape is attached to a first side of the plurality of lead frames and semiconductor dies are attached to respective ones of the die pads of the lead frames. Bond pads of the respective semiconductor dies are electrically connected to the lead fingers of the lead frames. Side walls of a footed lid are then attached to each of the lead frames to form a cavity on a second side of each of the lead frames. A gel material is dispensed within each of the cavities such that the gel material covers the semiconductor die and substantially fills gaps between the die pad and the lead fingers of each lead frame. A top cover is then attached to the side walls of the footed lid.

In another embodiment, the present invention is a packaged semiconductor device formed in accordance with the above-described method.

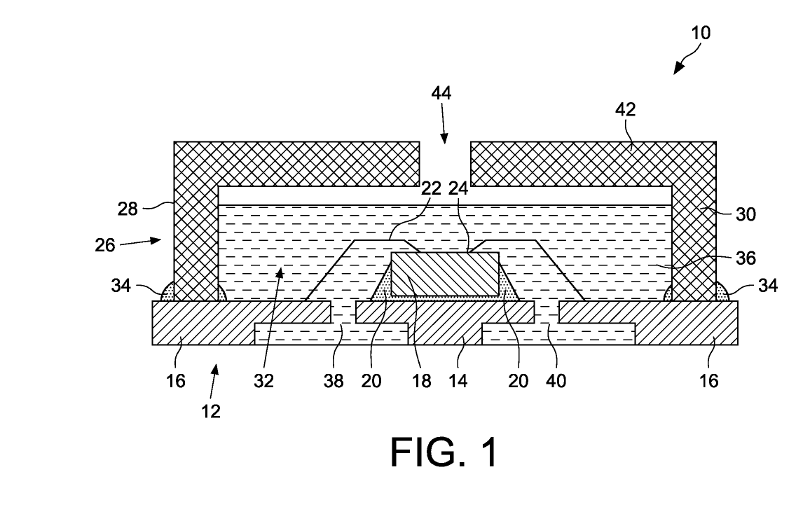

Referring now to FIG. 1, a cross-sectional view of a packaged semiconductor device 10 in accordance with an embodiment of the present invention is shown. The packaged semiconductor device 10 includes a lead frame 12 with a die pad 14 and lead fingers 16. The lead frame 12 may be formed of copper, an alloy of copper, a copper plated iron/nickel alloy, plated aluminum, or the like. In this exemplary embodiment of the invention, the die pad 14 and the ends of lead fingers 16 are half-etched.

A metal sheet may be processed to form the lead frame 12 with the die pad 14 and the lead fingers 16 using sawing, stamping and/or etching processes, as are known in the art. Alternatively, a pre-fabricated lead frame panel can be obtained from a separate supplier, where the lead frame already having been formed with die pads and lead fingers in a desired configuration.

A semiconductor die 18 is attached and electrically coupled to the lead frame 12. In this exemplary embodiment of the invention, the semiconductor die 18 includes a piezo resistive transducer (PRT) die. The semiconductor die 18 may be attached to the lead frame 12 using a die attach adhesive. The semiconductor die 18 and the lead frame 12 are well known components of semiconductor devices and thus detailed descriptions thereof are not necessary for a complete understanding of the present invention.

In this exemplary embodiment of the invention, the semiconductor die 18 is attached and electrically coupled to the lead fingers 16 of the lead frame 12 via wires 22. The wires 22 are bonded to pads on an active surface 24 of the semiconductor die 18 and to corresponding contact pads on the lead frame 12, using a well known wire bonding process and known wire bonding equipment. The wires 22 are formed from a conductive material such as aluminium or gold.

Another way of electrically connecting the semiconductor die 18 to the lead frame 12 is to connect bond pads of the semiconductor die 18 to the lead fingers 16 with flip-chip bumps (not shown) attached to an underside of the semiconductor die 18. The flip-chip bumps may include solder bumps, gold balls, molded studs, or combinations thereof.

The packaged semiconductor device 10 includes a footed lid 26 with side walls 28 and 30. The side walls 28, 30 are attached to the lead frame 12 such that a cavity 32 is formed. In this exemplary embodiment of the invention, the side walls 28, 30 are attached to respective lead fingers 16 with a lid attach adhesive 34 like non conductive epoxy. In one exemplary embodiment of the invention, the side walls 28, 30 are attached to tie bars (not shown) that extend outwardly from the die pad 14. The side walls 28, 30 are formed of a durable and stiff material so that the PRT die 18 is protected and so the environment within the cavity 32 formed by the side walls 28, 30 is stable. In a preferred embodiment, the side walls 28, 30 are formed of material such as stainless steel, plated metal or polymers.

A gel material 36 such as a silicon-based gel is deposited within the cavity 32 that covers the semiconductor die 18 and substantially fills gaps 38 and 40 between the die pad 14 and the lead fingers 16. A top cover 42 is then attached to the side walls 28 and 30 of the footed lid 26. Preferably, the top cover 42 is formed of metal and is attached to the side walls 28, 30 with an adhesive. However, other attachment mechanisms may be envisaged. The top cover 42 includes a vent hole 44 on a top surface of the top cover 42. The vent hole 44 is used to facilitate air pressure measurement. In one embodiment, the vent hole 44 is located at a center area of the top cover 42. The vent hole 44 may be formed in the top cover 42 by drilling, pressing, punching, etc. The example configuration of the packaged semiconductor device 10 of FIG. 1 may be employed in a flat no-leads package such as a quad flat no-leads (QFN) package.

In certain exemplary embodiments, the semiconductor die 18 of the device 10 is attached to a substrate such as a flexible or a laminated substrate instead of the lead frame 12, as discussed in more detail below. The use of a flexible or laminate substrate can prevent leakage of the gel material 36 from the device 10.

PRT devices typically use pre-molded lead frames, that is, metal lead frames with a mold compound formed thereon that forms a cavity in which the PRT die is disposed. However, pre-molded lead frames are expensive. Thus, the present invention provides a method of assembling a PRT device that does not use a pre-molded lead frame. Instead, a footed lid with side walls that form a cavity for a gel coating are used either in conjunction with a lead frame or with a substrate (e.g., printed wiring board).

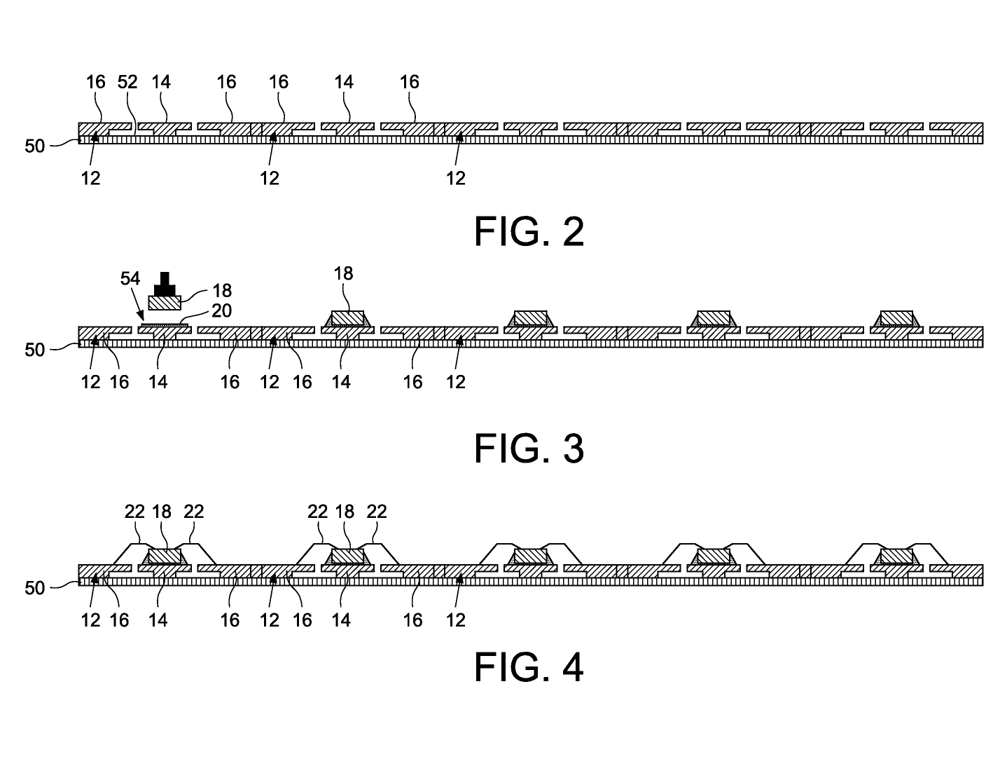

Referring now to FIGS. 2-9, a method of assembling a PRT device in accordance with an embodiment of the invention will be described. FIG. 2 is a side cross-sectional view showing a plurality of lead frames 12 with an adhesive tape 50 attached to a first side 52 of the lead frames 12. As illustrated, each lead frame 12 includes a die pad 14 and lead fingers 16.

The plurality of lead frames 12 may be available in the form of a single strip with adjacent individual segmented frames or in an array format.

FIG. 3 is an illustration of a step of attaching a semiconductor PRT die 18 to respective ones of the die pads 14 of the lead frames 12. The PRT dies 18 are attached to respective die pads 14 of the lead frames 12 with the die attach adhesive 20 such as die-bonding epoxy. The die attach adhesive 20 is dispensed on a top surface 54 of the lead frames 12 using a known dispensing device and the semiconductor dies 18 are placed on the die attach adhesive 20 to attach the dies 18 to the respective die pads 14. The die attach adhesive 20 may subsequently be cured in an oven or via light waves to harden the die attach adhesive 20.

FIG. 4 shows the step of electrically connecting the PRT die 18 to respective lead frames 12. In this exemplary embodiment of the invention, bond pads of the semiconductor dies 18 are electrically connected to the lead fingers 16 of the lead frames 12 with the wires 22 using a well known wire bonding process and known wire bonding equipment. In this exemplary embodiment, the bond pads of the respective semiconductor dies 18 are cleaned using a plasma treatment process prior to electrically connecting the bond pads to the lead fingers 16.

Another way of connecting the semiconductor dies 18 to the lead frames 12 is through flip-chip bumps (not shown) attached to an underside of the semiconductor die 18. The flip-chip bumps may include solder bumps, gold balls, molded studs, or combinations thereof. The bumps may be formed or placed on the semiconductor die 18 using known techniques such as evaporation, electroplating, printing, jetting, stud bumping and direct placement. Each semiconductor die 18 is flipped and the bumps are aligned with contact pads (not shown) of the lead fingers 16.

For the case in which the PRT device is assembled using a printed wiring board such as a substrate or flexible substrate, the PRT dies are attached to the substrate at predetermined locations using a die attach adhesive such as epoxy as is known in the art. The die attach step includes curing the epoxy such as with an oven. After curing, the substrate undergoes plasma cleaning and then the dies are electrically connected to the substrate via a wire bonding process using commercially available wire bonding equipment, also as is known in the art. That is, wires are used to interconnect bonding pads of the semiconductor die with electrical connection pads on the substrate. After wire bonding, side walls of the lids are attached to the substrate using an adhesive such as epoxy and the epoxy is cured, again an oven may be used for curing the epoxy. The remaining steps for forming a PRT device assembled with a substrate are as described below for the lead frame based device except for the de-taping step if a tape is not attached to the bottom of the substrate.

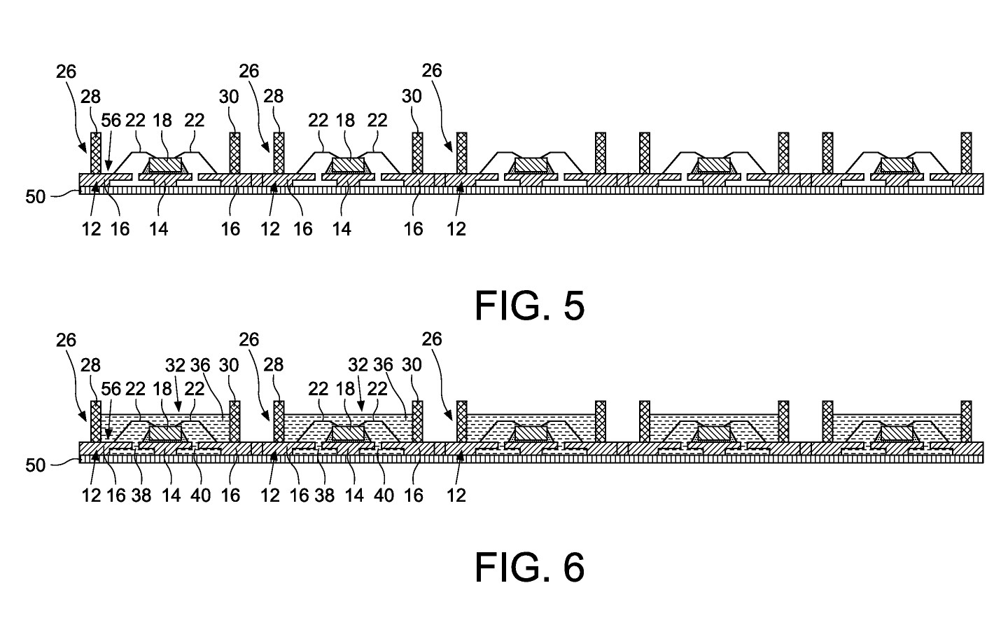

FIG. 5 shows the step of attaching side walls 28 and 30 of the footed lid 26 to each of the lead frames 12. In this exemplary embodiment of the invention, the side walls 28 and 30 are attached to respective lead fingers 16 of each of the lead frames 12 using a lid attach adhesive 34 to form a cavity 32 on a second side 56 of each of the lead frames 12. The lid attach adhesive is dispensed on a top surface of the lead fingers 16 using a known dispensing device and the side walls are placed on the lid attach adhesive 34 to attach the side walls 28 and 30 to the respective lead fingers 16. The lid attach adhesive 34 is subsequently cured in an oven.

FIG. 6 shows the step of dispensing a gel material 34 within each of the cavities 32. The gel material 36 such as a silicon-based gel may be dispensed to cover the semiconductor dies 18 and substantially fill gaps 38 and 40 between the die pad 14 and the lead fingers 16 of each lead frame 12. Te gel material 36 may be dispensed with a nozzle of a conventional dispensing machine, as is known in the art. Subsequently, the gel material 36 is cured in an oven. In this exemplary embodiment of the invention, each of the lead frames 12 is subjected to plasma cleaning prior to dispensing the gel material 36 within the cavity 32.

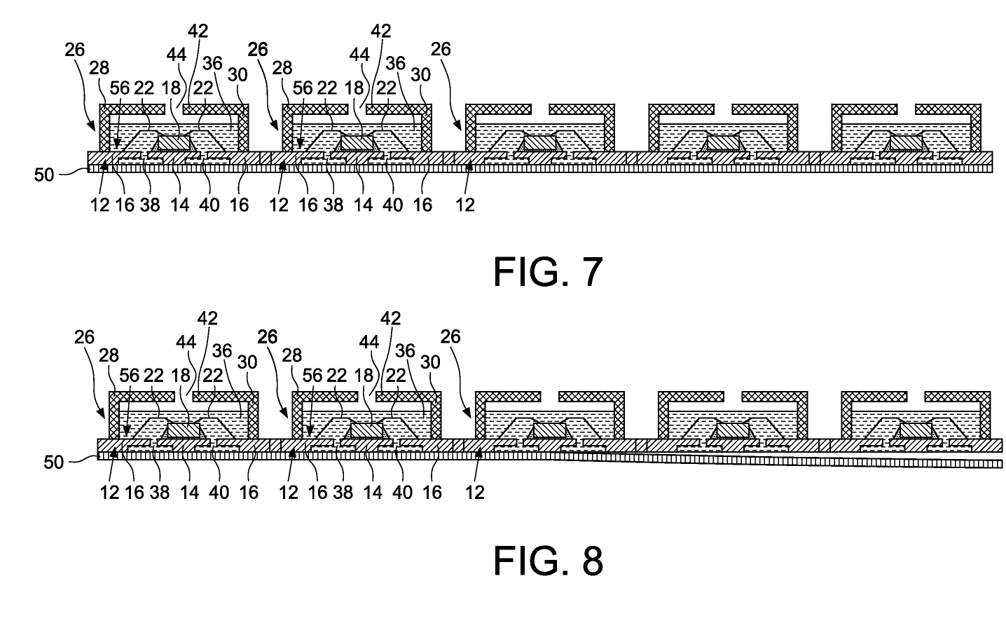

FIG. 7 is a side cross-sectional view showing a top cover 42 attached to the side walls 28 and 30 of the footed lid 26. In this exemplary embodiment of the invention, the top cover 42 includes a metal cover attached to the side walls 28 and 30 using an adhesive. The adhesive 34 is subsequently cured in a conventional oven followed by removal of the tape 50 from the lead frames 12, as shown in FIG. 8. As can be seen, the gel material 36 between the die pad 14 and the lead fingers 16 is exposed upon removal of the tape 50.

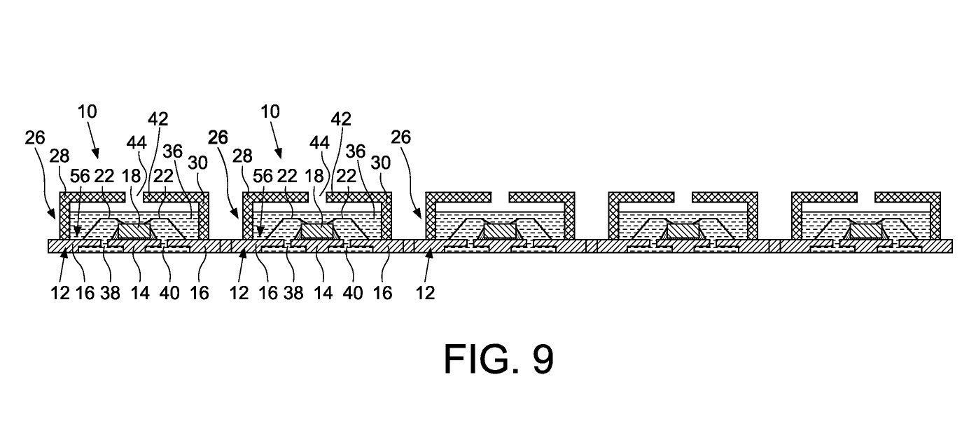

FIG. 9 shows the individual packaged semiconductor devices 10 being separated from each other by a singulation process. Singulation processes are well known and may include cutting with a saw or a laser. As illustrated, the plurality of lead frames 12 is singulated to form the individual packaged semiconductor devices 10.

The present invention, as described above, allows for packaging a semiconductor die without requiring premolded lead frames to package the die. A semiconductor die is attached to the die pad of the lead frame. Further, a footed lid is attached to the lead frame with side walls of the footed lid attached to lead fingers to form a cavity. A gel material is deposited within the cavity to cover the semiconductor die and substantially fill gaps between the doe pad and the lead fingers. Subsequently, a top cover of the lid is attached to the package without the need of a premolded lead frame.

Thus, the present invention provides a method of packaging semiconductor dies such as a pressure sensor die to form QFN packages with a lower package profile that does not require a premolded lead frame for facilitating lid attachment thereby reducing manufacturing costs for such packages. Moreover, the packaging technique described above prevents issues such as mold burr, mold flash, mold planarity and cavity wall inconsistency for such semiconductor device packages.

By now it should be appreciated that there has been provided an improved packaged semiconductor device and a method of forming the packaged semiconductor device. Circuit details are not disclosed because knowledge thereof is not required for a complete understanding of the invention. Although the invention has been described using relative terms such as “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A method of packaging a semiconductor sensor die, comprising the steps of:
providing a substrate having a first side including a die attach area and substrate electrical connection pads;
attaching a piezo resistive transducer (PRT) type semiconductor die to the die attach area;
electrically connecting bond pads of the PRT type semiconductor die to the substrate electrical connection pads;
attaching side walls of a footed lid to the first side of the substrate such that the side walls form a cavity and surround the PRT type semiconductor die and the electrical connections between the die and the substrate;
dispensing a gel material within the cavity such that the gel material covers the PRT type semiconductor die and substantially fills gaps between the die attach area and the substrate electrical connection pads; and
attaching a top cover to the side walls of the footed lid.

2. The method of packaging a semiconductor sensor die of claim 1, wherein the substrate comprises a flexible printed wiring board.

3. The method of packaging a semiconductor sensor die of claim 1, wherein the substrate comprises a lead frame, the die attach area comprises a lead frame flag, and the substrate electrical connection pads comprise lead fingers.

4. The method of packaging a semiconductor sensor die of claim 3, wherein attaching side walls of the footed lid to each of the lead frames comprises attaching the side walls of the footed lid to respective lead fingers of the lead frame with a lid attach adhesive and curing the lid attach adhesive.

5. The method of packaging a semiconductor sensor die of claim 3, wherein the die pad and at least one end of the lead fingers are half-etched.

6. The method of packaging a semiconductor sensor die of claim 3, further comprising attaching a second side of the lead frame to a tape before attaching the PRT type semiconductor die to the die pad and removing the tape after dispensing the gel material into the cavity.

7. The method of packaging a semiconductor sensor die of claim 6, wherein the gel material fills spaces between the lead fingers and the die pad and wherein an outer surface of the gel material in said spaces is exposed after removing the tape.

8. The method of packaging a semiconductor sensor die of claim 1, wherein attaching the top cover comprises attaching the cover to the side walls of the footed lid with an adhesive material and curing the adhesive material.

9. The method of packaging a semiconductor sensor die of claim 1, further comprising curing the gel material prior to attaching the top cover.

10. The method of packaging a semiconductor sensor die of claim 1, wherein the electrically connecting step comprises connecting the bond pads of the PRT type semiconductor die to the substrate electrical connection pads with wires using a wire bonding process.

11. The method of packaging a semiconductor sensor die of claim 1, further comprising plasma cleaning the substrate prior to dispensing the gel material within the cavity.

12. The method of packaging a semiconductor sensor die of claim 1, wherein the top cover includes a vent hole.

13. A packaged semiconductor sensor device, comprising:
a substrate including a die attach area and a plurality of electrical connection pads;
a piezo resistive transducer (PRT) semiconductor die attached to the substrate at the die attach area and electrically coupled to the substrate by way of the plurality of electrical connection pads;
a footed lid with side walls, wherein the side walls are attached to the substrate and surround the PRT semiconductor die such that a cavity is formed and the PRT semiconductor die is located within the cavity;
a gel material deposited within the cavity that covers the PRT semiconductor die and the electrical connections between the PRT semiconductor die and the substrate electrical connection pads; and
a top cover attached to the side walls of the footed lid.

14. The packaged semiconductor device of claim 13, wherein the top cover includes a vent hole.

15. The packaged semiconductor device of claim 13, wherein the die bonding pads are electrically coupled to substrate electrical connection pads with bond wires.

16. The packaged semiconductor device of claim 13, wherein the gel material comprises silicon-based gel.

17. The packaged semiconductor device of claim 13, wherein the substrate comprises a flexible printed wiring board.

18. The packaged semiconductor device of claim 13, wherein the substrate comprises a lead frame, the die attach area comprises a die pad of the lead frame, and the substrate electrical connection pads comprise lead fingers.

19. A method of packaging a semiconductor sensor die, comprising the steps of:
providing a substrate including a plurality of die attach areas and a plurality of sets of electrical connection pads, wherein one set of electrical connection pads is associated with each die attach area;
attaching piezo resistive transducer (PRT) type semiconductor dies to respective die attach areas of the substrate with a die attach adhesive and curing the die attach adhesive;
electrically connecting bond pads of the PRT type semiconductor dies to respective sets of the electrical connection pads;
attaching side walls of footed lids to the substrate such that respective ones of the side walls surround corresponding ones of the PRT type semiconductor dies with a lid attach adhesive, wherein the side walls form cavities and the PRT type semiconductor dies are located in respective ones of the cavities;
dispensing a gel material into the cavities such that the gel material covers the PRT type semiconductor dies;
attaching a top cover to the side walls of the footed lid with an adhesive material, wherein the top cover includes a vent hole; and
singulating the substrate to form individual packaged semiconductor sensor devices.

20. The packaged semiconductor device of claim 19, wherein the substrate comprises a flexible printed wiring board.
